(19) United States
(12) Patent Application Publication
(10) Pub. No.: US 2003/0108144 A1
(43) Pub. Date: Jun. 12, 2003

(54) Clock control method for preventing charge couple device from saturation

(76) Inventors: Summer Tseng, Chilung (TW); Shih-Huang Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/065,614

(22) Filed: Nov. 4, 2002

(30) Foreign Application Priority Data
Dec. 10, 2001 (TW) 90130495

(51) Int. Cl. G11C 19/28

(52) U.S. Cl. 377/62

(57) ABSTRACT

The present invention provides a clock control method for preventing the charge couple device from saturation. The charge couple device comprises a shift register, a last stage register and a pixel processing circuit. The clock control method for preventing the charge couple device from saturation is able to reduce the charge voltage sent to the last stage register from the shift register by controlling the signal transmission clock of the last stage register and the operating period of the reset clock of the pixel processing circuit, so as to prevent the saturation situation of the charge couple device from occurring. Moreover, better image quality is obtained by the proper clock control.

### CROSS REFERENCE TO RELATED APPLICATIONS

This application claims the priority benefit of Taiwan application serial no. 90130495, filed Dec. 10, 2001.

### BACKGROUND OF INVENTION

1. Field of Invention

The present invention generally relates to a clock control method for a scanner, and more particularly, to a clock control method used in the scanner to prevent the charge couple device from saturation.

2. Description of Related Art

The color charge couple device (CCD) is used as the photo sensor device for the general color scanner. The color charge couple device is composed of a plurality of the photo cells that are able to sense the photo intensity of the three original-colors including the Red, Green and Blue (R,G,B). FIG. 1 schematically shows the sketch map of the interleaved charge couple device. As shown in FIG. 1, after the photo cell 102 senses the photo intensity reflected by the document, the charge quantity corresponding to the photo intensity is accumulated in the photo cell 102. After the charge quantity is subsequently sent to the shift register 108 and 110 through the transfer gate 104 and 106 respectively, different charge voltages having the variant potentials are formed in the shift register 108 and 110.

The shift register 108 then sends every charge voltage to the last stage register 112 according to the timing intersection of the rising edge (or the falling edge) of the charge shift-out clock φ 1 and the falling edge (or the rising edge) of the shift-out clock φ 2. Similarly, the shift register 110 sends every charge voltage to the last stage register 114 according to the timing intersection of the rising edge (or the falling edge) of the charge shift-out clock φ 2 and the falling edge (or the rising edge) of the shift-out clock φ 1. FIG. 2 schematically shows the operating clock diagram of the conventional interleaved charge couple device. As shown in FIG. 2, the 1200 dpi interleaved charge couple device applied in the 100 dpi low resolution image scan is exemplified. In the period T1˜T6 of the charge shift-out clock φ 1 and φ 2, the shift register 110 sends the charge quantity of the six charge voltages (the charge voltage A₁, B₁, C₁, D₁, E₁ and F₁ for the charge shift-out clock φ 1 and the charge voltages A₂, B₂, C₂, D₂, E₂ and F₂ for the charge shift-out clock φ 2, as shown in FIG. 2) to the last stage register 114. In the period T6 of the charge shift-out clock φ 1 and φ 2, the signal transmission clock φ 1L is turned from “L” (i.e. low level) to “H” (i.e. high level), and the charge quantity of the six charge voltages stored by the last stage register 114 are sent to the pixel processing circuit 118. The reset clock φ RB is then turned from “L” to “H”, and inversely outputs the signal, which is turned from “H” to “L”, to the pixel processing circuit 118 through the inverter 116. During the period of the reset clock φ RB being in a “H” state, the charge quantity of charge voltages A₂, B₂, C₂, D₂, E₂ and F₂ by the signal transmission clock φ 2L will not be generated because of the reset clock φ RB. Afterwards, the pixel processing circuit 118 generates a reset voltage to clear the charge voltage that is sent to the pixel processing circuit 118 from the last stage register 114. The six charge voltages sent from the shift register 110 to the last stage register 114 are all discarded. That is, the charge voltages sent from the shift register 110 to the last stage register 114 are all cleared and discarded by the pixel processing circuit 118. Thus, the description below does not include the circuit operating relationship among the shift register 110, the last stage register 114 and the pixel processing circuit 118 with respect to the signal transmission clock φ 2L.

FIG. 2 schematically describes the clock operation by referring to FIG. 1. In the period T1 of the charge shift-out clock φ 1 and φ 2, the shift register 108 sends the charge voltage A₁ to the last stage register 112, the signal transmission clock φ 1L is “L”, so the charge quantity of the charge voltage A₁ is preserved in the last stage register 112.

In the period T2 of the charge shift-out clock φ 1 and φ 2, the shift register 108 sends the charge voltage B₁ to the last stage register 112, the signal transmission clock φ 1L is still kept in “L”, the last stage register 112 accumulates the charge quantity of the charge voltage A₁ and charge voltage B₁ and preserves the charge voltage of the charge quantity accumulated. The positioning clock CP is then turned from “L” to “H”, so that the pixel processing circuit 118 generates a positioning voltage.

In the period T3 of the charge shift-out clock φ 1 and φ 2, the shift register 108 sends the charge voltage C₁ to the last stage register 112, the signal transmission clock φ 1L is still kept in “L”, the last stage register 112 accumulates the charge quantity of the charge voltage A₁, charge voltage B₁ and charge voltage C₁, and preserves the charge voltage of the accumulated charge quantity. The sampling clock CDS1 is then turned from “L” to “H”, such that the pixel processing circuit 118 samples the potential of the sampling voltage and uses it as the reference potential for comparison.

In the period T4 of the charge shift-out clock φ 1 and φ 2, the shift register 108 sends the charge voltage D to the last stage register 112, the signal transmission clock φ 1L is still kept in “L”, the last stage register 112 accumulates the charge quantity of the charge voltage A₁ charge voltage B₁ charge voltage C₁ and voltage D₁, and preserves the charge voltage of the accumulated charge quantity.

In the period T5 of the charge shift-out clock φ 1 and φ 2, the shift register 108 sends the charge voltage E₁ to the last stage register 112, the signal transmission clock φ 1L is still kept in “L”, the last stage register 112 accumulates the charge quantity of the charge voltage A₁ charge voltage B₁, charge voltage C₁, charge voltage D₁ and charge voltage E₁ and preserves the charge voltage of the accumulated charge quantity.

In the period T6 of the charge shift-out clock φ 1 and φ 2, the shift register 108 sends the charge voltage F₁ to the last stage register 112, the signal transmission clock φ 1L is turned from “L” to “H”, the last stage register 112 accumulates the charge quantity of the charge voltage A₁, charge voltage B₁, charge voltage C₁, charge voltage D₁, charge voltage E₁ and charge voltage F₁, and ends the charge voltage of the accumulated charge quantity to the pixel processing circuit 118, and the sampling clock CDS2 is turned from “L” to “H”. The pixel processing circuit 118 then samples the charge voltage of the accumulated charge quantity. The difference of the charge voltage and the positioning voltage that was sampled previously is the photo intensity sensed by the photo cell 102. After the image data process is finished by the pixel processing circuit 118, the reset clock φ RB is turned from “L” to “H”, and inversely outputs the signal, that is turned from “H” to “L”, to the pixel processing circuit 118 through the inverter 116. The pixel processing circuit 118 subsequently generates a reset voltage to clear the charge voltage that is sent to the pixel processing circuit 118 from the last stage register 112. Therefore, the pixel processing circuit 118 is able to implement the next image data process.

As described above, the capacity of the charge quantity stored by the last stage register 112 is the same as the capacity of the charge quantity stored by the shift register 108. The charge quantity of the six charge voltages are sent to the last stage register 112 by the shift register 108. When the accumulated charge quantity of the six charge voltages exceeds the charge quantity that can be stored by the last stage register 112, the surplus portion is lost due to the saturation of the charge quantity stored by the last stage register 112. Therefore, the photo intensity sensed by the photo cell 102 cannot be reflected correctly.

To solve the problem mentioned above, one of the methods is to shorten the exposure time of the charge couple device. When the exposure time of the charge couple device is shortened, the charge quantity sensed by the photo cell is reduced, the sensed charge quantity is sent to the shift register from the photo cell, and the charge quantity temporarily stored in the shift register is subsequently sent to the last stage register. Therefore, the charge quantity accumulated in the last stage register is less likely to exceed the charge quantity stored by the last stage register itself. Thus, the saturation problem is less likely to happen to the charge couple device.

However, when the exposure time of the charge couple device is reduced, the time for the charge couple device to send out the voltage signal is reduced accordingly. That is, the period of each clock for the photo cell to send the sensed charge quantity to the shift register, the shift register subsequently to send the charge quantity temporarily stored in the shift register to the last stage register, and for the last stage register to send the accumulated charge quantity to the pixel processing circuit is also reduced accordingly, so that the frequency of each clock is getting faster. If the frequency of the operating clock of the charge couple device is getting faster, the signal sensed by the charge couple device is easily interfered by high frequency noise, such that the distortion of the image occurs. Moreover, due to the limitation of the mechanical structure of the scanner (such as the rotation speed of the step motor), the exposure time of the charge couple device can not be unlimitedly shortened, thus the saturation problem of the charge couple device cannot be solved completely.

### SUMMARY OF INVENTION

Therefore, the present invention provides a clock control method for preventing the charge couple device from saturation. The method controls the signal transmission clock and the operating period of the reset clock, such that the saturation situation of the stored charge quantity does not occur in the last stage register.

The present invention provides a clock control method for preventing the charge couple device from saturation. The charge couple device comprises a shift register, a last stage register and a pixel processing circuit. The method for preventing the charge couple device from saturation comprises the steps of: At first, in the first accumulated period of the signal transmission clock, the last stage register receives the charge voltage sent from the shift register, as an accumulated voltage. Then, in the first shift-out period of the signal transmission clock, the last stage register sends the accumulated voltage to the pixel processing circuit. Afterwards, in the non-reset period of the reset clock, the photo intensity corresponding to the accumulated voltage sent to the pixel processing circuit is obtained. Furthermore, in the second accumulated period of the signal transmission clock, the last stage register receives the charge voltage sent from the shift register, as an abandoned voltage. Moreover, in the second shift-out period of the signal transmission clock, the last stage register sends the abandoned voltage to the pixel processing circuit. And, in the reset period of the rest clock, the pixel processing circuit generates a reset voltage to clear the abandoned voltage that is sent to the pixel processing circuit from the last stage register. Therefore, the signal transmission clock and the operating period of the rest clock are controlled to reduce the charge voltage sent to the last stage register from the shift register to prevent the charge couple device from the saturation situation.

### BRIEF DESCRIPTION OF DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1 schematically shows a sketch map of the conventional interleaved charge couple device;

FIG. 2 schematically shows an operating clock diagram of the conventional interleaved charge couple device;

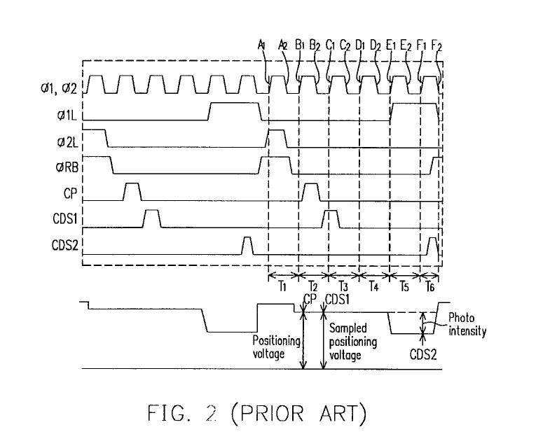

FIG. 3 schematically shows an operating clock diagram of the interleaved charge couple device according to the present invention.

### DETAILED DESCRIPTION

In order to solve the saturation problem of the charge couple device, that results from a plurality of the shift registers sending the charge voltage to the last stage register, so that the last register accumulates too much charge quantity, in the conventional art, the present invention controls the operating clock of the charge couple device to reduce the quantity of the charge voltage that is sent to the last stage register from the shift register. Therefore, the charge quantity accumulated in the last stage register is not too much, keeping the saturation situation of the charge couple device from occurring.

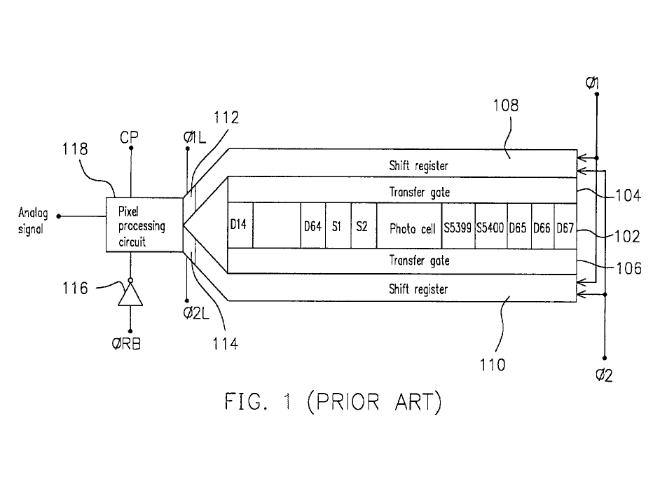

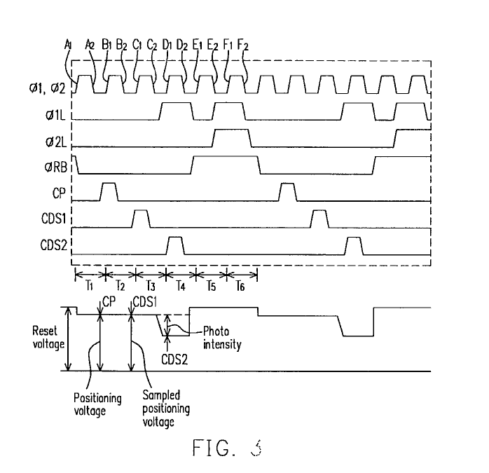

Please refer to FIG. 3, and FIG. 1 is also used as a reference to describe the method for solving the problem mentioned above. FIG. 3 schematically shows the operating clock diagram of the interleaved charge couple device according to the present invention. In FIG. 3, the 1200 dpi interleaved charge couple device applied in the 100 dpi low resolution image scanning is similarly exemplified. As described above, in the six periods of the charge shift-out clock φ 1 and φ 2, the shift register 110 sends the charge quantity of the six charge voltages (such as the charge voltages A₁, B₁, C₁, D₁, E₁ and F₁ for the charge shift-out clock φ 1 and the charge voltages A₂, B₂, C₂, D₂, E₂ and F₂ for the charge shift-out clock φ 2, as shown in FIG. 3) to the last stage register 114. When the signal transmission clock φ 2L is turned from “L” to “H”, the charge quantity of the six charge voltages stored by the last stage register 114 is sent to the pixel processing circuit 118. When the reset clock φ RB is turned from “L” to “H”, the signal that is turned from “H” to “L” is inversely output to the pixel processing circuit 118 through the inverter 116. The pixel processing circuit 118 subsequently generates a reset voltage to clear the charge voltage that is sent to the pixel processing circuit 118 from the last stage register 114. The six charge voltages sent to the last stage register 114 from the shift register 110 are all discarded. That is, the charge voltages sent from the shift register 110 to the last stage register 114 are all cleared and discarded by the pixel processing circuit 118. Thus, the description below does not include the circuit operating relationship among the shift register 110, the last stage register 114 and the pixel processing circuit 118 with respect to the signal transmission clock φ 2L.

In the period T1 of the charge shift-out clock φ 1 and φ 2, the shift register 108 sends the charge voltage A₁ to the last stage register 112, the signal transmission clock φ 1L is turned from “L” to “H”, so that the last stage register 112 sends the charge quantity of the preserved charge voltage A₁ to the pixel processing circuit 118. The reset clock φ RB is in the “H” state, and the “L” signal is inversely output to the pixel processing circuit 118 through the inverter 116. The pixel processing circuit 118 subsequently generates a reset voltage to clear the charge voltage A₁ that is sent to the pixel processing circuit 118 from the last stage register 112.

In the period T2 of the charge shift-out clock φ 1 and φ 2, the shift register 108 sends the charge voltage B₁ to the last stage register 112, and the signal transmission clock φ 1L has been turned from “H” to “L”. The last stage register 112 preserves the charge quantity of the charge voltage B₁. The positioning clock CP is then turned from “L” to “H”, so that the pixel processing circuit 118 generates a positioning voltage.

In the period T3 of the charge shift-out clock φ 1 and φ 2, the shift register 108 sends the charge voltage C₁ to the last stage register 112, the signal transmission clock φ 1L is still kept in “L”, and the last stage register 112 accumulates the charge quantity of the charge voltage B₁ and charge voltage C₁ and preserves the charge voltage of the accumulated charge quantity.

In the period T4 of the charge shift-out clock φ 1 and φ 2, the shift register 108 sends the charge voltage D₁ to the last stage register 112, the signal transmission clock φ 1L is still kept in “L”, and the last stage register 112 accumulates the charge quantity of the charge voltage B₁ charge voltage C₁ and charge voltage D₁, and preserves the charge voltage of the accumulated charge quantity. The sampling clock CDS1 is then turned from “L” to “H”, so that the pixel processing circuit 118 samples the potential of the positioning voltage, and makes it as the reference potential for comparison.

In the period T5 of the charge shift-out clock φ 1 and φ 2, the shift register 108 sends the charge voltage E to the last stage register 112, and the signal transmission clock φ 1L is turned from “L” to “H”. The last stage register 112 accumulates the charge quantity of the charge voltage B₁ charge voltage C₁ charge voltage D₁ and charge voltage E₁ and sends the charge voltage of the accumulated charge quantity to the pixel processing circuit 118. The sampling clock CDS2 is then turned from “L” to “H”, and the pixel processing circuit 118 samples the charge voltage of the accumulated charge quantity. The difference of the charge voltage and the positioning voltage that was sampled previously is the photo intensity sensed by the photo cell 102.

In the period T6 of the charge shift-out clock φ 1 and φ 2, the shift register 108 sends the charge voltage F₁ to the last stage register 112, and the signal transmission clock φ 1L is turned from “H” to “L”. The last stage register 112 accumulates the charge quantity of the charge voltage F₁ and waits for the next charge voltage (such as the charge voltage A₁ shown in FIG. 3) to store it into the last stage register 112. The charge voltage of the charge quantity accumulated by the last stage register 112 is subsequently sent to the pixel processing circuit 118. When the reset clock φ RB is turned from “L” to “H” again, the pixel processing circuit 118 generates a reset voltage, and the reset voltage is used to clear the charge voltage sent from the last stage register 112.

As described above, originally, the charge quantity of the six charge voltages is sent from the shift register 108 to the last stage register 112. However, by changing the operating period of the signal transmission clock φ 1L with respect to the reset clock φ RB, the charge quantity of the four charge voltages that is sent to the pixel processing circuit 118 from the last stage register 112 (such as the charge voltage B, D, E and F shown in FIG. 3) is transformed into an analog signal by the pixel processing circuit 118. The charge quantity of the two charge voltages (such as the charge voltage A and F shown in FIG. 3) sent from the last stage register 112 are discarded by the pixel processing circuit 118. Therefore, when it is determined to have shift register 108 send the charge quantity of a plurality of the charge voltages to the last stage register 112, the saturation problem of the charge couple device can be solved by easily modifying the operating period of the signal transmission clock φ 1L with respect to the reset clock φ RB. Moreover, each clock of the charge couple device is not operated in very high frequency, thus the signal sensed by the charge couple device is not interfered by high frequency noise, so distortion of the image does not occur.

Therefore, the advantage of the present invention is in controlling the signal transmission clock and the operating period of the reset clock to reduce the quantity of the charge voltage sent from the shift register to the last stage register. Thus, the charge quantity accumulated by the last stage register is not too much, so as to prevent the saturation situation of the charge couple device from occurring.

Another advantage of the present invention is each clock of the charge couple device is not operated in high frequency. Thus, the signal sensed by the charge couple device is not interfered by the high frequency noise, so the image distortion situation does not occur.

Although the invention has been described with reference to a particular embodiment thereof, it will be apparent to one of ordinary skill in the art that modifications to the described embodiment may be made without departing from the spirit of the invention. Accordingly, the scope of the invention will be defined by the attached claims not by the above detailed description.

1. A clock control method for preventing the charge couple device from saturation, wherein the charge couple device comprises a shift register, a last stage register and a pixel processing circuit; wherein the method for preventing the charge couple device from saturation comprises the steps of:
in a first accumulated period of a signal transmission clock, the last stage register receiving a charge voltage sent by the shift register, as an accumulated voltage;
in a first shift-out period of the signal transmission clock, the last stage register sending the accumulated voltage to the pixel processing circuit;
in a non-reset period of a reset clock, obtaining a photo intensity corresponding to the accumulated voltage sent to the pixel processing circuit;
in a second accumulated period of the signal transmission clock, the last stage register receiving the charge voltage sent by the shift register, as an abandoned voltage;
in a second shift-out period of the signal transmission clock, the last stage register sending the abandoned voltage to the pixel processing circuit; and
in a reset period of the reset clock, the pixel processing circuit generating a reset voltage to clear the abandoned voltage sent from the last stage register to the pixel processing circuit.

2. The method of claim 1, wherein the shift register sends the charge voltage to the last stage register according to either a rising edge or a falling edge of a charge shift-out clock.

3. The method of claim 1, wherein in the first shift-out period of the signal transmission clock, the shift register sends the charge voltage to the last stage register and the last stage register subsequently sends the charge voltage to the pixel processing circuit.

4. The method of claim 1, wherein in the second shift-out period of the signal transmission clock, the shift register sends the charge voltage to the last stage register and the last stage register subsequently sends the charge voltage to the pixel processing circuit.

5. The method of claim 1, wherein the clock control method for preventing the charge couple device from saturation is the clock control method for preventing the interleaved charge couple device from saturation.
